(19) United States
(12) Patent Application Publication
(10) Pub. No.: US 2020/0351862 A1
(43) Pub. Date: Nov. 5, 2020

(54) Reed Muller Block Code for SPUCCH

(71) Applicant: Telefonaktiebolaget LM Ericsson (publ), Stockholm (SE)

(72) Inventors: Mattias Andersson, Sundbyberg (SE); Gustav Almquist, Järfälla (SE); Mårten Sundberg, Årsta (SE)

(21) Appl. No.: 16/760,287

(22) PCT Filed: Oct. 30, 2018
(86) PCT No.: PCT/IB2018/058510

§ 371 Date: Apr. 29, 2020

Related U.S. Application Data
(60) Provisional application No. 62/579,600, filed on Oct. 31, 2017.

(51) Int. Cl. H04W 72/04; H04L 1/00; H03M 13/13; H03M 13/00

(52) U.S. Cl. CPC H04W 72/0413; H03M 13/616; H03M 13/136; H04L 1/0072

(57) ABSTRACT

According to an aspect, a wireless device is configured to transmit control data for transmission in a short physical uplink control channel, sPUCCH, that can carry only 24 coded bits. The wireless device codes 11 bits of the control data into 12 encoded bits using a 12-row Reed-Muller generator matrix having full rank and transmits the 12 encoded bits in the SPUCCH. According to another aspect, a wireless device is configured to transmit control data for transmission in an sPUCCH that can carry only 24 coded bits per resource block allocated to the sPUCCH transmission. The wireless device determines that there are 21 or 22 bits of control data to be encoded for transmission in the sPUCCH and allocates at least 2 resource blocks to the sPUCCH transmission.

### TECHNICAL FIELD

The present invention generally relates to wireless communication networks, and particularly relates to transmitting control data for transmission in a short physical uplink control channel (sPUCCH) that can carry only 24 coded bits or only 24 coded bits per resource block allocated to the sPUCCH transmission.

### BACKGROUND

In 3rd-Generation Partnership Project (3GPP) Long Term Evolution (LTE) systems, data transmissions in both downlink (i.e., from a network node or eNB to a user equipment or UE) and uplink (from a UE to a network node) are organized into radio frames of 10 ms, each radio frame consisting of ten equally-sized subframes of length Tsubframe=1 ms, as shown in FIG. 1.

LTE uses orthogonal frequency-division multiplexing (OFDM) in the downlink and Discrete Fourier Transform spread (DFT-spread) OFDM (also referred to as single-carrier frequency-division multiple access, or FDMA) in the uplink. The basic LTE downlink physical resource can thus be seen as a time-frequency grid as illustrated in FIG. 2, where each resource element corresponds to one OFDM subcarrier during one OFDM symbol interval. The uplink subframe has the same subcarrier spacing/bandwidth as the downlink and the same number of single carrier FDMA (SC-FDMA) symbols in the time domain as OFDM symbols in the downlink.

Furthermore, the resource allocation in LTE is typically described in terms of resource blocks (RBs), where a resource block corresponds to one slot (0.5 ms) in the time domain and 12 contiguous subcarriers in the frequency domain A pair of two adjacent resource blocks in time direction (1.0 milliseconds) is known as a resource block pair. Resource blocks are numbered in the frequency domain, starting with 0 from one end of the system bandwidth.

Similarly, the LTE uplink resource grid is illustrated in FIG. 3, where N_{RB}^{UL} is the number of RBs contained in the uplink system bandwidth, N_{sc}^{RB} is the number subcarriers in each RB, typically N_{sc}^{RB}=12, N_{symb}^{UL} is the number of SC-FDMA symbols in each slot. N_{symb}^{UL}=7 for normal cyclic prefix (CP) and N_{symb}^{UL}=6 for extended CP. A subcarrier and a SC-FDMA symbol forms an uplink resource element (RE).

Downlink transmissions from an eNB to a UE are dynamically scheduled, i.e., in each subframe the base station transmits control information about which terminals data is transmitted to and upon which resource blocks the data is transmitted, in the current downlink subframe. This control signaling is typically transmitted in the first 1, 2, 3 or 4 OFDM symbols in each subframe and the number n=1, 2, 3 or 4 is known as the Control Format Indicator (CFI). The downlink subframe also contains common reference symbols, which are known to the receiver and used for coherent demodulation of the control information. A downlink system with CFI=3 OFDM symbols as control is illustrated in FIG. 4.

The reference symbols shown in FIG. 4 are the cell specific reference symbols (CRS) and are used to support multiple functions including fine time and frequency synchronization and channel estimation for certain transmission modes.

Transmissions in the uplink (from a UE to an eNB) are, as in the downlink, also dynamically scheduled through the downlink control channel. When a UE receives an uplink grant in subframe n, it transmits data in the uplink at subframe n+k, where k=4 for frequency division duplex (FDD) system and k varies for time division duplex (TDD) systems.

In LTE, a number of physical channels are supported for data transmissions. A downlink or an uplink physical channel corresponds to a set of resource elements carrying information originating from higher layers, while a downlink or an uplink physical signal is used by the physical layer but does not carry information originating from higher layers. Some of the downlink physical channels supported in LTE are: Physical Downlink Shared Channel (PDSCH); Physical Downlink Control Channel (PDCCH); and Enhanced Physical Downlink Control Channel (EPDCCH). Some of the downlink signals supported in LTE are reference signals: Cell Specific Reference Signals (CRS); DeModulation Reference Signal (DMRS) for PDSCH; and oChannel State Information Reference Signals (CSI-RS).

PDSCH is used mainly for carrying user traffic data and higher layer messages in the downlink and is transmitted in a downlink subframe outside of the control region as shown in FIG. 4. Both PDCCH and EPDCCH are used to carry Downlink Control Information (DCI) such as PRB allocation, modulation level and coding scheme (MCS), precoder used at the transmitter, etc. PDCCH is transmitted in the first one to four OFDM symbols in a downlink subframe, i.e., the control region, while EPDCCH is transmitted in the same region as PDSCH.

Some of the uplink physical channels supported in LTE are: Physical Uplink Shared Channel (PUSCH); Physical Uplink Control Channel (PUCCH); DMRS for PUSCH; and DMRS for PUCCH.

The PUSCH is used to carry uplink data or/and uplink control information from the UE to the eNodeB. The PUCCH is used to carry uplink control information from the UE to the eNodeB.

Carrier aggregation was introduced in LTE Release 10. If a UE is configured with carrier aggregation (CA), it can receive or transmit data on different frequency carriers at the same time (i.e., in the same subframe). This increases the UE throughput. For example, a UE is configured with downlink carrier aggregation of carrier 0 that is 10 MHz bandwidth and carrier 1 that has 20 MHz bandwidth. The UE can get, in the same subframe, a downlink assignment for receiving a 10 MHz PDSCH on carrier 0 and a downlink assignment for receiving a 20 MHz PDSCH on carrier 1. Note that a carrier is also commonly named component carrier. The term serving cell is also used to refer to a carrier from a UE perspective.

Latency Reduction with Shortened Processing Time and Short TTI

Packet data latency is one of the performance metrics that vendors, operators, and end-users (via speed test applications) regularly measure. Latency measurements are done in all phases of a radio access network system lifetime, when verifying a new software release or system component, when deploying a system and when the system is in commercial operation.

Shorter latency, than present in previous generations of 3GPP RATs, was one performance metric that guided the design of LTE. The end-users also now recognize LTE to be a system that provides faster access to the internet and lower data latencies than previous generations of mobile radio technologies.

Packet data latency is important not only for the perceived responsiveness of the system, it is also a parameter that indirectly influences the throughput of the system. HyperText Transfer Protocol/Transmission Control Protocol (HTTP/TCP) is the dominating application and transport layer protocol suite used on the internet today. According to HTTP Archive (http://httparchive.org/trends.php), the typical size of HTTP based transactions over the internet are in the range of a few 10's of Kbyte up to 1 Mbyte. In this size range, the TCP slow start period is a significant part of the total transport period of the packet stream. During TCP slow start, the performance is latency limited. Hence, improved latency can rather easily be showed to improve the average throughput, for this type of TCP-based data transactions. Latency reductions could positively impact radio resource efficiency. Lower packet data latency could increase the number of transmissions possible within a certain delay bound, leading to higher Block Error Rate (BLER) targets for the data transmissions and freeing up radio resources. This can improve the capacity of the system.

One approach to latency reduction is the reduction of processing time at the UE. In legacy LTE, the delay between an uplink grant and an uplink transmission is specified. Similarly, the delay between a downlink data transmission and the downlink hybrid automatic repeat request (HARQ) feedback is specified. In LTE FDD, this delay is set to 4 ms. HARQ feedback for a downlink data transmission received in subframe n is sent by the UE in subframe n+4. In LTE Release 15, this processing time is shortened to 3 ms. The shortened processing time feature is configured for a UE over higher layer, i.e., radio resource control (RRC). The shortened processing time feature can be configured independently for each carrier configured for a UE. Another discussed option is to configure shortened processing time for a group of component carriers.

Another approach enabling the reduction of transport time of data and control signaling is to reduce the length of a transmission time interval (TTI). By reducing the length of a TTI and maintaining the bandwidth, the processing time at the transmitter and the receiver nodes is also expected to be reduced, due to less data to process within the TTI. As described above, in LTE Release 8, a TTI corresponds to one subframe of length 1 millisecond. One such 1 ms TTI is constructed by using 14 OFDM or SC-FDMA symbols in the case of normal cyclic prefix and 12 OFDM or SC-FDMA symbols in the case of extended cyclic prefix. In LTE release 15, shorter TTIs, such as a slot or a few symbols, are being specified.

An sTTI can be decided to have any duration in time, comprise resources on any number of OFDM or SC-FDMA symbols, and start at a specific symbol position within the overall frame. For LTE, the focus of current work is to only allow the sTTIs to start at fixed positions with durations of either 2, 3 or 7 symbols. Furthermore, the sTTI is not allowed to cross either slot nor subframe boundaries. The duration of 2 or 3 symbols is referred to as a subslot transmission, while the 7 symbol duration is referred to as a slot transmission.

FIG. 5 shows an example of a 2/3-symbol sTTI configuration within an uplink subframe. Here, the duration of the uplink short TTI is 0.5 ms, i.e., seven SC FDMA symbols for the case with normal cyclic prefix. Also, a combined length of 2 or 3 symbols is shown for the sTTI. Here, the “R” in the figures indicates the DMRS symbols, and “D” indicates the data symbols. Other configurations are not excluded, and the figure is only an attempt to illustrated differences in sTTI lengths.

The allowed sTTI combinations for downlink and uplink in LTE are illustrated by FIG. 6.

### Short Physical Uplink Control Channel (SPUCCH)

The Short Physical Uplink Control Channel (SPUCCH) will shorten the time duration of the uplink control channel (compared to the longer 1 ms operation in LTE) to facilitate faster signaling.

The SPUCCH channel is supported using 2 or 3 SC-FDMA symbols and 7 SC-FDMA symbols for formats based on the legacy PUCCH format 1, 3 and 4. These can be referred to as subslot-SPUCCH and slot-SPUCCH. Besides these formats, a new format based on sequence selection using different cyclic shifts of a base sequence is used.

Specifically, one of the agreed formats is the subslot-SPUCCH format 4 using a Reed Muller (RM) channel code. This variant of the SPUCCH format is agreed to support payloads from 3 bits to 22 bits.

As can be seen in FIG. 5, there will be one or two symbols available for data transmission and hence there are 12 subcarriers*2 bits/symbol (QPSK)=24 bits available in case of one data symbol and one resource block to carry the SPUCCH payload. It should be noted that SPUCCH format 4 can be carried over multiple resource blocks in frequency, in which case more coded bits are also available.

Construction of Codewords from Basis Sequence

Given a basis sequence, or generator matrix, for a (32,0) code, as shown in the table illustrated in FIG. 7, a codeword consisting of coded bits bᵢ is generated from K uncoded bits aₙ by

$${\tilde{b}}_{i} = {\sum }_{n = 0}^{K - 1} ( {a}_{n} \cdot {M}_{i , n} ) mod 2$$

followed by circular repetition or puncturing bᵢ=\tilde{b}_{(imod32)}. The RM block code is defined to take unencoded data in the range of 3 to 11 bits and encode that into codewords of lengths that fill up the available data symbols in the (S)PUCCH. The available data bits per unique data symbol in the (S)PUCCH is 24 bits. The codeword is mapped over the total number of available bits from all unique data symbols in the (S)PUCCH. “Unique” in this case refers to that the data mapped on the symbol is not mapped on any other symbol, which could be the case if, for example, Orthogonal Cover Codes (OCCs) are used. Since the RM block code only supports up to 11 bits of payload, two codewords are used if the payload is 12 to 22 bits long. If two codewords are used, the available bits from all unique data symbols are split equally between the two codewords, and the length of each codeword is half of what it would have been if only one codeword would have been used.

This becomes problematic for the specified (3GPP TS 36.212) RM block code when there is only 1 data symbol available to be transmitted over one resource block and 2 codewords are used where at least one codeword has 11 uncoded bits as input. This is the case for the 2 SC-FDMA symbols long PUCCH format 4 based format that uses the RM block code. The SPUCCH format only has 1 data symbol and when the input to the block code is 21 or 22 bits, at least one of the codewords gets 11 uncoded bits. Since the total available bits for data only is 24 bits, this leaves only 12 bits of encoded bits per codeword. The RM block code is shown in FIG. 7. As can be seen in FIG. 7, if the input is 11 bits (all columns are used) and the codeword length is 12 bits (first 12 rows are used), then the first and the last column are identical with all is (shown in bold font for rows 0-11). Having 2 columns identical means that 2 different uncoded messages get coded into the same codeword, i.e., all codewords occur twice in the codebook. It becomes impossible to decode; hence, it does not work.

### SUMMARY

Embodiments described herein provide for redefining the Reed-Muller (RM) code, at least under certain circumstances, so that 21 and 22 uncoded bits no longer result in undecodable codewords. The embodiments make it possible to use payloads of 21 and 22 bits for 2 SC-FDMA symbols long SPUCCH format 4 with RM.

According to some embodiments, a method for transmitting control data for transmission in an sPUCCH that can carry only 24 coded bits includes coding 11 bits of the control data into 12 encoded bits using a 12-row Reed-Muller generator matrix having full rank. The method also includes transmitting the 12 encoded bits in the SPUCCH.

According to some embodiments, a method for transmitting control data for transmission in an sPUCCH that can carry only 24 coded bits per resource block allocated to the sPUCCH transmission includes determining that there are 21 or 22 bits of control data to be encoded for transmission in the sPUCCH and allocating at least 2 resource blocks to the sPUCCH transmission.

According to some embodiments, a wireless device is configured to transmit control data for transmission in an sPUCCH that can carry only 24 coded bits. The wireless device includes transceiver circuitry and processing circuitry operatively associated with the transceiver circuitry. The processing circuitry is configured to code 11 bits of the control data into 12 encoded bits using a 12-row Reed-Muller generator matrix having full rank and transmit the 12 encoded bits in the SPUCCH.

According to some embodiments, a wireless device is configured to transmit control data for transmission in an sPUCCH that can carry only 24 coded bits per resource block allocated to the sPUCCH transmission. The wireless device includes transceiver circuitry and processing circuitry operatively associated with the transceiver circuitry. The processing circuitry is configured to determine that there are 21 or 22 bits of control data to be encoded for transmission in the sPUCCH and allocating at least 2 resource blocks to the sPUCCH transmission.

Other aspects of the disclosed technology include a transmitter apparatus, computer program products and computer readable media configured to carry out the methods summarized above, and variants. These and various other methods and apparatus corresponding to the above aspects are detailed herein, as are additional details and refinements of these aspects. Of course, the present invention is not limited to the above features and advantages. Those of ordinary skill in the art will recognize additional features and advantages upon reading the following detailed description, and upon viewing the accompanying drawings.

### BRIEF DESCRIPTION OF THE DRAWINGS

FIG. 1 illustrates a diagram of an LTE time-domain structure.

FIG. 2 illustrates a diagram of an LTE downlink physical resource.

FIG. 3 illustrates a diagram of an LTE uplink resource grid.

FIG. 4 illustrates a diagram of an LTE downlink subframe.

FIG. 5 illustrates an example of a 2/3-symbol sTTI configuration within an uplink subframe.

FIG. 6 illustrates allowed sTTI combinations for downlink and uplink in LTE.

FIG. 7 illustrates a (32,0) RM block code.

FIG. 8 illustrates a generator matrix constructed from the 12 last rows of the table of FIG. 7, according to some embodiments.

FIG. 9 illustrates a generator matrix that adds a parity bit, according to some embodiments.

FIG. 10 illustrates an example embodiment of restricting the payload bits in certain configurations.

FIG. 11 illustrates a block diagram of a wireless device, according to some embodiments.

FIG. 12 is a process flow diagram illustrating a method, according to some embodiments.

FIG. 13 is a process flow diagram illustrating another method, according to some embodiments.

FIG. 14 illustrates a block diagram of a network node, according to some embodiments.

FIG. 15 illustrates a functional implementation of a wireless device, according to some embodiments.

FIG. 16 illustrates another functional implementation of a wireless device, according to some embodiments.

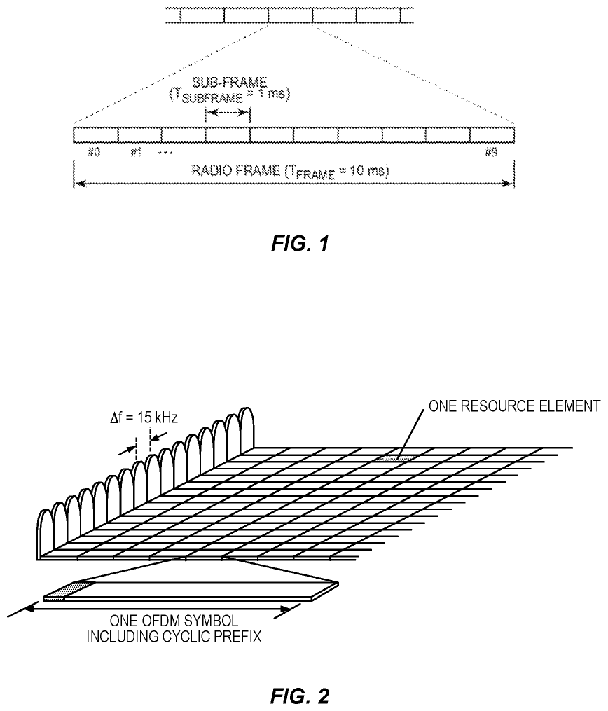

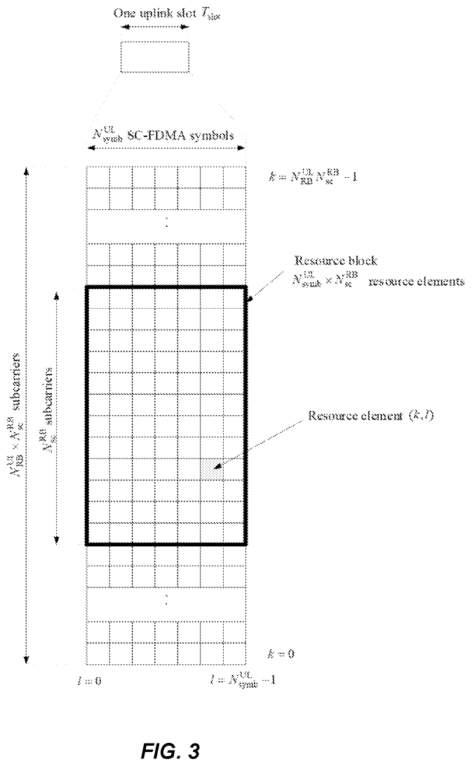

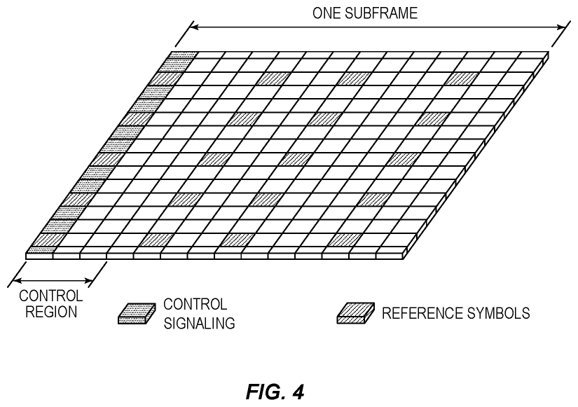

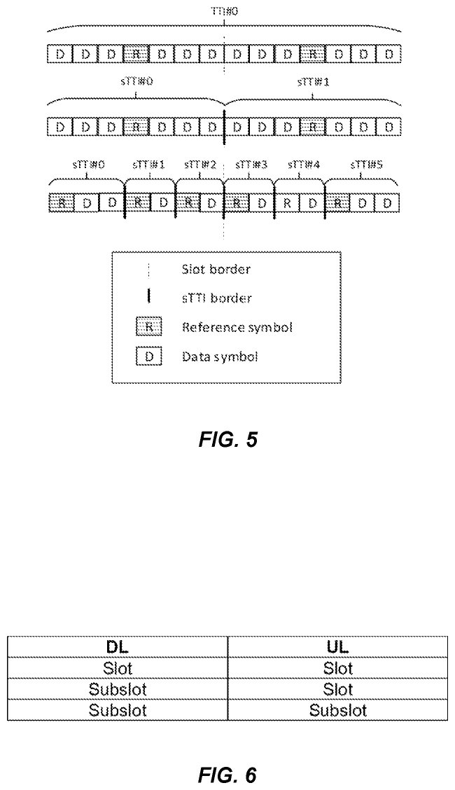

### DETAILED DESCRIPTION

As stated earlier, the problem with 2 SC-FDMA symbols long SPUCCH format 4 using RM with 21 and 22 bits is that the effective part of the generator matrix does not have full rank, i.e., that 2 columns are linearly dependent, in this case they become the same.

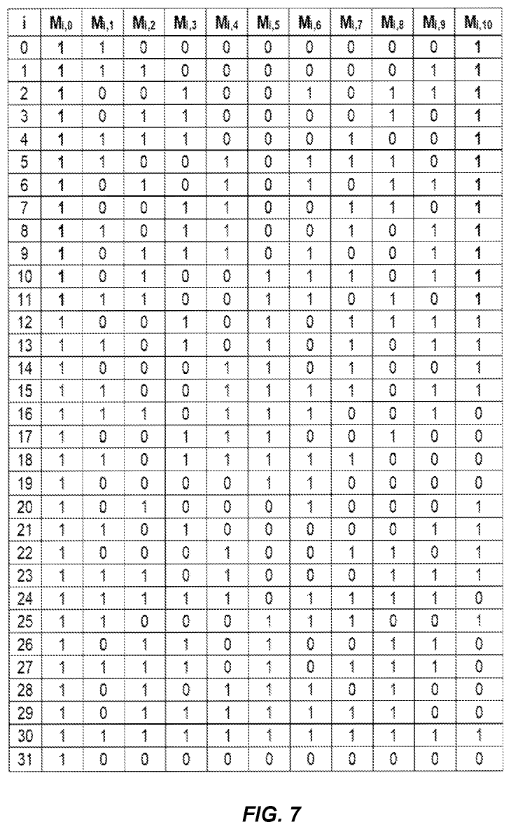

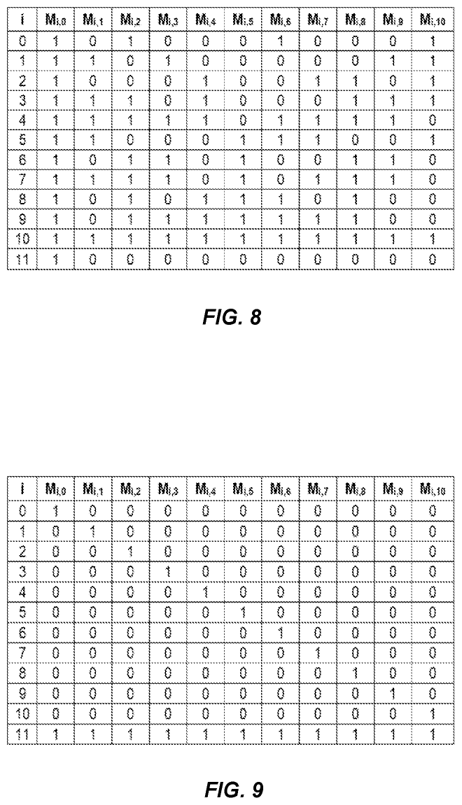

Because of this issue, a new generator matrix for the problematic cases are required. One way to get a working generator matrix in these cases is to take the last 12 rows of the table in FIG. 7, instead of the first 12 rows. This gives the generator matrix in the table illustrated in FIG. 8, where the illustrated matrix is of full rank and the codewords become fully decodable.

Another way to address this issue is to define a completely new generator matrix for 21 and 22 bits payload. This new generator matrix could then, of course, also be used for all other payloads as well, if seen to be beneficial.

A very simple way to define a new generator matrix is to note the fact that when coding 11 bits into 12 bits, the code rate is very close to 1, so a simplification could be to repeat the uncoded bits and add a parity bit. For example, the generator matrix in FIG. 9, which simply adds a parity bit to uncoded bits, can be used.

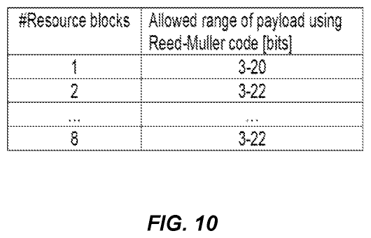

Since the problem occurs for the case of a single resource block being allocated to the SPUCCH format 4 transmission, one embodiment includes not allowing the number of payload bits to be sent where they do not result in a uniquely decodable codeword. One example of restricting the payload bits in certain configurations is shown in FIG. 10.

Some embodiments may include a combination of at least one of the following:
Redefining the RM generator matrix for 2 SC-FDMA symbols long SPUCCH using PUCCH format 4 and payloads of 21 and 22 bits.
The RM generator matrix can be redefined by, instead of using the first 12 rows of the table of FIG. 7, using the last 12 rows (FIG. 8).
The RM generator matrix can be redefined by using any subset of 12 rows of the table in FIG. 7 that results in a matrix of full rank.
The RM generator matrix can be redefined by constructing a new generator matrix of full rank.
The RM generator matrix can be redefined by repeating the uncoded payload and adding a parity bit, for example as in FIG. 9.
Instead of only redefining the generator matrix for the case specified in the first bullet, a new, or multiple new generator matrices can be used for all SPUCCH cases and payloads using RM.
The range of payload bits allowed to be used for a given resource allocation can be restricted to avoid the codeword not being uniquely decodable. One such restriction could be to not allow a payload size of 21 or 22 bits in the case where only a single resource block is being allocated to subslot-SPUCCH format 4.
The RM generator matrix can be redefined by using any subset of a suitable number of rows of the table in FIG. 7 that results in a matrix of full rank.

Embodiments of the present invention enable encoding of 21 and 22 bits payload messages using 2 SC-FDMA symbols long PUCCH format 4 mapped over 1 resource block using RM. Without this particular encoding, the decoding is not possible.

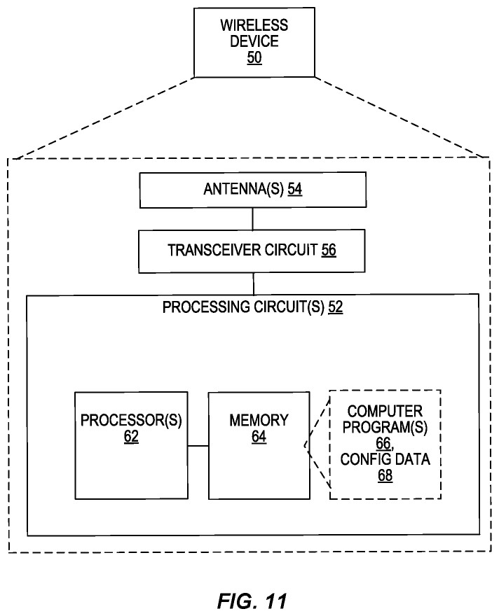

FIG. 11 illustrates a diagram of a transmitting apparatus, shown as wireless device 50, according to some embodiments. The wireless device 50 can be any type of wireless device capable of communicating with a network node or another wireless device (e.g., UE) over radio signals. The wireless device 50 may also be radio communication device, target device, device to device (D2D) UE, V2X UE, ProSe UE, machine type UE or UE capable of machine to machine communication (M2M), a sensor equipped with UE, PDA (personal digital assistant), iPAD, Tablet, mobile terminals, smart phone, laptop embedded equipped (LEE), laptop mounted equipment (LME), USB dongles, Customer Premises Equipment (CPE), etc.

The wireless device 50 communicates with a radio node or base station via antennas 54 and a transceiver circuit 56. The transceiver circuit 56 may include transmitter circuits, receiver circuits, and associated control circuits that are collectively configured to transmit and receive signals according to a radio access technology, for the purposes of providing cellular communication services.

The wireless device 50 also includes one or more processing circuits 52 that are operatively associated with the radio transceiver circuit 56. The processing circuitry 52 comprises one or more digital processing circuits 62, e.g., one or more microprocessors, microcontrollers, Digital Signal Processors (DSPs), Field Programmable Gate Arrays (FPGAs), Complex Programmable Logic Devices (CPLDs), Application Specific Integrated Circuits (ASICs), or any mix thereof. More generally, the processing circuitry 52 may comprise fixed circuitry, or programmable circuitry that is specially adapted via the execution of program instructions implementing the functionality taught herein, or may comprise some mix of fixed and programmed circuitry. The processing circuitry 52 may be multi-core.

The processing circuitry 52 also includes a memory 64. The memory 64, in some embodiments, stores one or more computer programs 66 and, optionally, configuration data 68. The memory 64 provides non-transitory storage for the computer program 66 and it may comprise one or more types of computer-readable media, such as disk storage, solid-state memory storage, or any mix thereof. By way of non-limiting example, the memory 64 comprises any one or more of SRAM, DRAM, EEPROM, and FLASH memory, which may be in the processing circuitry 52 and/or separate from the processing circuitry 52. In general, the memory 64 comprises one or more types of computer-readable storage media providing non-transitory storage of the computer program 66 and any configuration data 68 used by the wireless device 50. Here, “non-transitory” means permanent, semi-permanent, or at least temporarily persistent storage and encompasses both long-term storage in non-volatile memory and storage in working memory, e.g., for program execution.

The wireless device 50, e.g., using the processing circuitry 52, may be configured to perform all or some of the techniques described above. For example, the processor 62 of the processor circuitry 52 may execute a computer program 66 stored in the memory 64 that configures the processor 62 to transmit control data for transmission in a sPUCCH that can carry only 24 coded bits. The processing circuitry 52 of the wireless device 50 may thus be configured to code 11 bits of the control data into 12 encoded bits using a 12-row Reed-Muller generator matrix having full rank and transmit the 12 encoded bits in the SPUCCH.

In other embodiments, the processing circuitry 52 is configured to transmit control data for transmission in a sPUCCH that can carry only 24 coded bits per resource block allocated to the sPUCCH transmission. The processing circuitry 52 is configured to determine that there are 21 or 22 bits of control data to be encoded for transmission in the sPUCCH and allocate at least 2 resource blocks to the sPUCCH transmission.

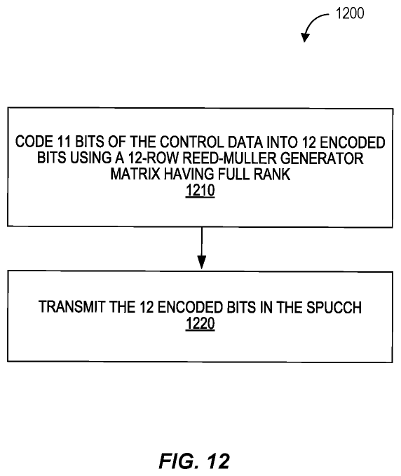

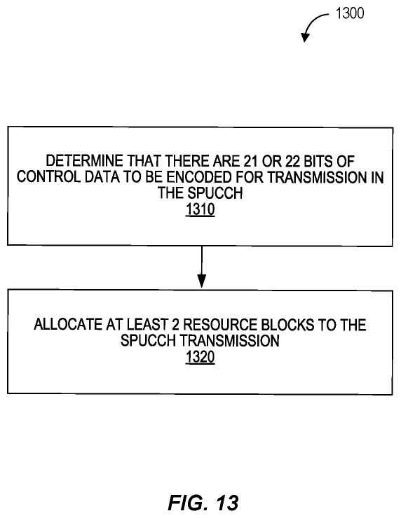

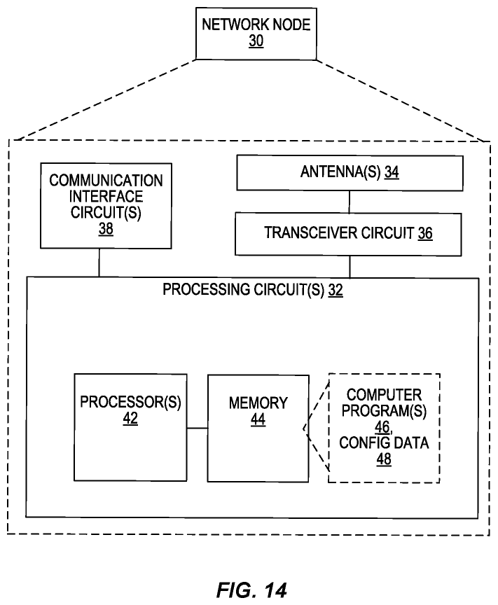

The processing circuitry 52 may be configured to perform corresponding methods, such as methods 1200 and 1300, illustrating in respective FIGS. 12 and 13. Method 1200, according to some embodiments, includes coding 11 bits of the control data into 12 encoded bits using a 12-row Reed-Muller generator matrix having full rank (block 1210) and transmitting the 12 encoded bits in the SPUCCH (block 1220).

The 12-row Reed-Muller generator matrix may consist of 12 rows selected from a predetermined 32-row Reed-Muller generator matrix otherwise used for encoding control data for transmission in a long PUCCH. The predetermined 32-row Reed-Muller generator matrix may be defined as in FIG. 7. The predetermined 32-row Reed-Muller generator matrix may be defined as in Section 5.2.2.6.4-1 of 3GPP TS 36.212. The 12 rows selected from the predetermined 32-row Reed-Muller generator matrix may consist of the bottom 12 rows of the predetermined 32-row Reed-Muller generator matrix.

The 12-row Reed-Muller generator matrix may be configured to encode the 11 bits of the control data into 12 encoded bits by adding a single parity bit to the 11 bits of the control data.

The method 1200 may include coding 10 or 11 additional bits of control data into 12 additional encoded bits, using the 12-row Reed-Muller generator matrix having full rank and transmitting the 12 additional encoded bits in the SPUCCH.

The method 1200 may also include first determining that there are 21 or 22 bits of control data to be encoded for transmission in the sPUCCH, and selectively using the 12-row Reed-Muller generator matrix having full rank for coding the 11 bits of the control data, instead of a default Reed-Muller generator matrix, in response to the determining. The 12-row Reed-Muller generator matrix having full rank may be selectively used further in response to determining that transmission in the sPUCCH is constrained to one Single-Carrier Frequency-Division Multiple Access (SC-FDMA) symbol, in one 12-subcarrier resource block.

The method 1200 may include transmitting the 12 encoded bits in the SPUCCH comprises transmitting the 12 encoded bits using Quadrature Phase-Shift Keying modulation and one SC-FDMA symbol, in one 12-subcarrier resource block.

As for method 1300, the method 1300 includes, according to some embodiments, determining that there are 21 or 22 bits of control data to be encoded for transmission in the sPUCCH (block 1310) and allocating at least 2 resource blocks to the sPUCCH transmission (block 1320).

The method 1300 may include coding 11 bits of the control data into N encoded bits using a predetermined 32-row Reed-Muller generator matrix, where N equals 12 times the number of allocated resource bits. The method 1300 may further include coding an additional 10 or 11 bits of the control data into N additional encoded bits; using the predetermined 32-row Reed-Muller generator matrix and transmitting the N encoded bits and the N additional encoded bits in the SPUCCH, using the allocated at least 2 resource blocks. The predetermined 32-row Reed-Muller generator matrix may be defined as in FIG. 7. The predetermined 32-row Reed-Muller generator matrix may be defined as in Section 5.2.2.6.4-1 of 3GPP TS 36.212, for example.

FIG. 13 illustrates a diagram of a network node 30, such as a base station, that can decode the uplink transmissions according to the coding performed by the wireless device 50, according to some embodiments. The network node 30 facilitates communication between wireless devices and the core network. Network node is a more general term and can correspond to any type of radio network node or any network node, which communicates with a UE and/or with another network node. Examples of network nodes are NodeB, base station (BS), multi-standard radio (MSR) radio node such as MSR BS, eNodeB, gNodeB. MeNB, SeNB, network controller, radio network controller (RNC), base station controller (BSC), road side unit (RSU), relay, donor node controlling relay, base transceiver station (BTS), access point (AP), transmission points, transmission nodes, RRU, RRH, nodes in distributed antenna system (DAS), core network node (e.g. MSC, MME, etc), O&M, OSS, SON, positioning node (e.g. E-SMLC) etc.

The network node 30 includes communication interface circuitry 38 that includes circuitry for communicating with other nodes in the core network, radio nodes, and/or other types of nodes in the network for the purposes of providing data and cellular communication services. The network node 30 communicates with wireless devices via antennas 34 and transceiver circuitry 36. The transceiver circuitry 36 may include transmitter circuits, receiver circuits, and associated control circuits that are collectively configured to transmit and receive signals according to a radio access technology, for the purposes of providing cellular communication services.

The network node 30 also includes one or more processing circuits 32 that are operatively associated with the communication interface circuitry 38 and/or the transceiver circuitry 36. The network node 30 uses the communication interface circuitry 38 to communicate with network nodes and the transceiver circuitry 36 to communicate with user equipments. For ease of discussion, the one or more processing circuits 32 are referred to hereafter as “the processing circuitry 32.” The processing circuitry 32 comprises one or more digital processors 42, e.g., one or more microprocessors, microcontrollers, DSPs, FPGAs, CPLDs, ASICs, or any mix thereof. More generally, the processing circuitry 32 may comprise fixed circuitry, or programmable circuitry that is specially configured via the execution of program instructions implementing the functionality taught herein, or may comprise some mix of fixed and programmed circuitry. The processor 42 may be multi-core, i.e., having two or more processor cores utilized for enhanced performance, reduced power consumption, and more efficient simultaneous processing of multiple tasks.

The processing circuitry 32 also includes a memory 44. The memory 44, in some embodiments, stores one or more computer programs 46 and, optionally, configuration data 48. The memory 44 provides non-transitory storage for the computer program 46 and it may comprise one or more types of computer-readable media, such as disk storage, solid-state memory storage, or any mix thereof. By way of non-limiting example, the memory 44 comprises any one or more of SRAM, DRAM, EEPROM, and FLASH memory, which may be in the processing circuitry 32 and/or separate from the processing circuitry 32. In general, the memory 44 comprises one or more types of computer-readable storage media providing non-transitory storage of the computer program 46 and any configuration data 48 used by the network node 30.

The processing circuitry 32 is configured, in some embodiments, to decode the transmissions in the sPUCCH that are coded with 11 bits of the control data into 12 encoded bits using a 12-row Reed-Muller generator matrix having full rank.

The processing circuitry 32 is also configured, in some embodiments, to decode the transmissions in the sPUCCH that are allocated at least 2 RBs to the sPUCCH transmission upon a determination that there are 21 or 22 bits of control data to be encoded for transmission in the sPUCCH.

In other words, according to various embodiments of the techniques described herein, the wireless device 50 and the network node 30 can perform communications using various combinations of the techniques described above, e.g., in connection with FIGS. 12 and 13.

The term signal used herein can be any physical signal or physical channel. Examples of downlink physical signals are reference signal such as a primary synchronization signal (PSS), secondary synchronization signal (SSS), cell-specific reference signals (CRS), positioning reference signal (PRS), channel state information RS (CSI-RS), demodulation reference signal (DMRS), narrowband reference signal (NRS), narrowband primary synchronization signal (NPSS), narrowband secondary synchronization signal (NSSS), synchronization signal (SS), multicast-broadcast single-frequency network (MBSFN) RS, etc. Examples of uplink physical signals are reference signal such as sounding reference signal (SRS), DMRS, etc. The term physical channel (e.g., in the context of channel reception) used herein is also called as ‘channel. The physical channel carries higher layer information (e.g. RRC, logical control channel, etc). Examples of downlink physical channels are physical broadcast channel (PBCH), narrowband physical broadcast channel (NPBCH), physical downlink control channel (PDCCH), physical downlink shared channel (PDSCH), short physical downlink shared channel (SPDSCH), machine-type communication physical downlink control channel (MPDCCH), narrowband physical downlink control channel (NPDCCH), narrowband physical downlink shared channel (NPDSCH), enhanced physical downlink control channel (E-PDCCH), etc. Examples of uplink physical channels are short physical uplink control channel (SPUCCH), short physical uplink shared channel (SPUSCH), physical uplink shared channel (PUSCH), physical uplink control channel (PUCCH), narrowband physical uplink shared channel (NPUSCH), physical random access channel (PRACH), narrowband physical random access channel (NPRACH), etc.

The transmission time may correspond to any type of physical resource or radio resource expressed in terms of length of time. Signals are transmitted or received by a radio node over a time resource. Examples of time resources are: symbol, time slot, subslot, subframe, radio frame, TTI, interleaving time, etc.

The term TTI used herein may correspond to any time period (TO) over which a physical channel can be encoded and interleaved for transmission. The physical channel is decoded by the receiver over the same time period (TO) over which it was encoded. The TTI may also interchangeably called as short TTI (sTTI), transmission time, slot, subslot, mini-slot, short subframe (SSF), mini-subframe, etc.

It should be appreciated that the processing circuitry 52 of FIG. 11 can be understood to implement a number of functional modules, where each functional module may represent a module of software or firmware executing on a processing circuit, or a functional grouping of digital hardware, or a combination of both. Each functional module may correspond to one or more of the steps illustrated in the process flow diagrams of FIGS. 12 and 13, for example.

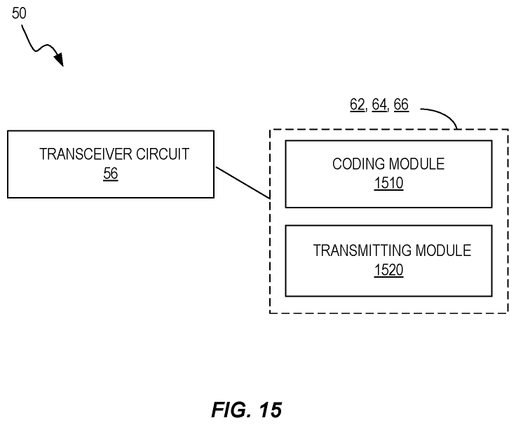

In such an example, FIG. 15 illustrates a wireless device 50 for transmitting control data for transmission in a sPUCCH that can carry only 24 coded bits. The wireless device 50 functionally includes a coding module 1510 for coding 11 bits of the control data into 12 encoded bits using a 12-row Reed-Muller generator matrix having full rank, and a transmitting module 1520 for transmitting the 12 encoded bits in the SPUCCH.

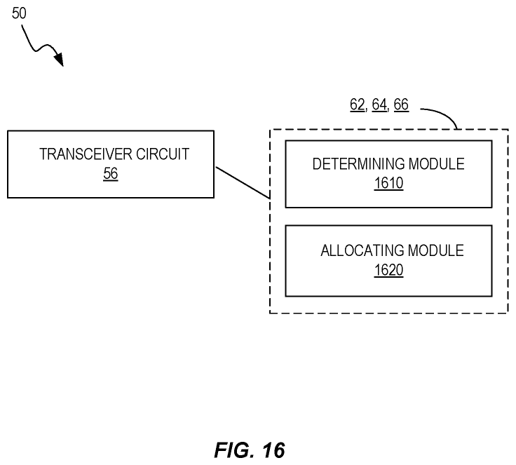

In another example, FIG. 16 illustrates a wireless device 50 for transmitting control data for transmission in a sPUCCH that can carry only 24 coded bits per resource block allocated to the sPUCCH transmission. The wireless device 50 functionally includes a determining module 1610 for determining that there are 21 or 22 bits of control data to be encoded for transmission in the sPUCCH, and an allocating module 1620 for allocating at least 2 resource blocks to the sPUCCH transmission.

Modifications and other embodiments of the disclosed invention(s) will come to mind to one skilled in the art having the benefit of the teachings presented in the foregoing descriptions and the associated drawings. Therefore, it is to be understood that the invention(s) is/are not to be limited to the specific embodiments disclosed and that modifications and other embodiments are intended to be included within the scope of this disclosure. Although specific terms may be employed herein, they are used in a generic and descriptive sense only and not for purposes of limitation.

1-33. (canceled)

34. A method for transmitting control data for transmission in a short physical uplink control channel (sPUCCH) that can carry only 24 coded bits per resource block allocated to the sPUCCH transmission, the method comprising:
determining that there are 21 or 22 bits of control data to be encoded for transmission in the sPUCCH; and
allocating at least two resource blocks to the sPUCCH transmission.

35. The method of claim 34, the method further comprising:
coding eleven bits of the control data into N encoded bits using a predetermined 32-row Reed-Muller generator matrix, where N equals 12 times the number of allocated resource bits;
coding an additional ten or eleven bits of the control data into N additional encoded bits;
using the predetermined 32-row Reed-Muller generator matrix; and
transmitting the N encoded bits and the N additional encoded bits in the SPUCCH, using the allocated at least two resource blocks.

36. The method of claim 35, wherein the predetermined 32-row Reed-Muller generator matrix is defined in the table of FIG. 7.

37. The method of claim 35, wherein the predetermined 32-row Reed-Muller generator matrix is defined in Section 5.2.2.6.4-1 of 3GPP TS 36.212.

38. A method for transmitting control data for transmission in a short physical uplink control channel (sPUCCH) that can carry only 24 coded bits, the method comprising:
coding eleven bits of the control data into twelve encoded bits using a twelve-row Reed-Muller generator matrix having full rank; and
transmitting the twelve encoded bits in the SPUCCH.

39. The method of claim 38, wherein the twelve-row Reed-Muller generator matrix consists of 12 rows selected from a predetermined 32-row Reed-Muller generator matrix otherwise used for encoding control data for transmission in a long PUCCH.

40. The method of claim 39, wherein the predetermined 32-row Reed-Muller generator matrix is defined in the table of FIG. 7.

41. The method of claim 39, wherein the predetermined 32-row Reed-Muller generator matrix is defined in Section 5.2.2.6.4-1 of 3GPP TS 36.212.

42. The method of claim 40, wherein the twelve rows selected from the predetermined 32-row Reed-Muller generator matrix consist of the bottom twelve rows of the predetermined 32-row Reed-Muller generator matrix.

43. The method of claim 38, wherein the twelve-row Reed-Muller generator matrix is configured to encode the eleven bits of the control data into twelve encoded bits by adding a single parity bit to the eleven bits of the control data.

44. The method of claim 38, further comprising:
coding ten or eleven additional bits of control data into twelve additional encoded bits, using the twelve-row Reed-Muller generator matrix having full rank; and
transmitting the twelve additional encoded bits in the SPUCCH.

45. The method of claim 38, wherein the method further comprises:
first determining that there are 21 or 22 bits of control data to be encoded for transmission in the sPUCCH, and selectively using the twelve-row Reed-Muller generator matrix having full rank for coding the eleven bits of the control data, instead of a default Reed-Muller generator matrix, in response to said determining.

46. The method of claim 45, wherein said selectively using the twelve-row Reed-Muller generator matrix having full rank is further in response to determining that transmission in the sPUCCH is constrained to one Single-Carrier Frequency-Division Multiple Access (SC-FDMA) symbol, in one twelve-subcarrier resource block.

47. The method of claim 38, wherein transmitting the twelve encoded bits in the SPUCCH comprises transmitting the twelve encoded bits using Quadrature Phase-Shift Keying modulation and one Single-Carrier Frequency-Division Multiple Access (SC-FDMA) symbol, in one twelve-subcarrier resource block.

48. A wireless device configured to transmit control data for transmission in a short physical uplink control channel (sPUCCH) that can carry only 24 coded bits per resource block allocated to the sPUCCH transmission, the wireless device comprising:
transceiver circuitry; and
processing circuitry operatively associated with the transceiver circuitry and configured to:
determine that there are 21 or 22 bits of control data to be encoded for transmission in the sPUCCH; and
allocate at least two resource blocks to the sPUCCH transmission.

49. The wireless device of claim 48, wherein the processing circuitry is configured to:
code eleven bits of the control data into N encoded bits using a predetermined 32-row Reed-Muller generator matrix, where N equals twelve times the number of allocated resource bits;
code an additional ten or eleven bits of the control data into N additional encoded bits;
using the predetermined 32-row Reed-Muller generator matrix; and
transmit the N encoded bits and the N additional encoded bits in the SPUCCH, using the allocated at least two resource blocks.

50. The wireless device of claim 49, wherein the predetermined 32-row Reed-Muller generator matrix is defined in the table of FIG. 7.

51. The wireless device of claim 49, wherein the predetermined 32-row Reed-Muller generator matrix is defined in Section 5.2.2.6.4-1 of 3GPP TS 36.212.

52. A wireless device configured to transmit control data for transmission in a short physical uplink control channel (sPUCCH) that can carry only 24 coded bits, the wireless device comprising:
transceiver circuitry; and
processing circuitry operatively associated with the transceiver circuitry and configured to:
code eleven bits of the control data into twelve encoded bits using a twelve-row Reed-Muller generator matrix having full rank; and
transmit the twelve encoded bits in the SPUCCH.

53. The wireless device of claim 52, wherein the twelve-row Reed-Muller generator matrix consists of twelve rows selected from a predetermined 32-row Reed-Muller generator matrix otherwise used for encoding control data for transmission in a long PUCCH.
